(19) United States
(12) Patent Application Publication
(10) Pub. No.: US 2015/0228463 A1
(43) Pub. Date: Aug. 13, 2015

(54) CLEANING PROCESS FOR CLEANING AMORPHOUS CARBON DEPOSITION RESIDUALS USING LOW RF BIAS FREQUENCY APPLICATIONS

(71) Applicant: Applied Materials, Inc., Santa Clara, CA (US)

(72) Inventors: Pramit MANNA, Santa Clara, CA (US); Prashant Kumar KULSHRESHTHA, San Jose, CA (US); Kwangduk Douglas LEE, Redwood City, CA (US); Martin Jay SEAMONS, San Jose, CA (US); Abhijit Basu MALLICK, Fremont, CA (US); Bok Hoen KIM, San Jose, CA (US); Mukund SRINIVASAN, Fremont, CA (US)

(21) Appl. No.: 14/619,138

(22) Filed: Feb. 11, 2015

Related U.S. Application Data
(60) Provisional application No. 61/938,491, filed on Feb. 11, 2014.

(51) Int. Cl. H01J 37/32; B08B 7/00

(52) U.S. Cl. CPC H01J 37/32862; B08B 7/00; H01J 37/32155; H01J 37/32715; H01J 37/3244; H01J 2237/332; H01J 2237/335

(57) ABSTRACT

Methods for cleaning a processing chamber to remove amorphous carbon containing residuals from the processing chamber are provided. The cleaning process utilizes a low frequency RF bias power during the cleaning process. In one embodiment, a method of cleaning a processing chamber includes supplying a cleaning gas mixture into a processing chamber, applying a RF bias power of about 2 MHz or lower to a substrate support assembly disposed in the processing chamber to form a plasma in the cleaning gas mixture in the processing chamber, and removing deposition residuals from the processing chamber.

### CROSS-REFERENCE TO RELATED APPLICATIONS

This application claims benefit of U.S. Provisional Application Ser. No. 61/938,491 filed Feb. 11, 2014 (Attorney Docket No. APPM/21504), which is incorporated by reference in its entirety.

### BACKGROUND

1. Field

Embodiments of the present invention relate to the fabrication of integrated circuits and to a cleaning process for cleaning a processing chamber after forming a hardmask layer. More specifically, embodiments of the present invention relate to a cleaning process for cleaning a processing chamber after forming a hardmask layer utilizing low RF frequency bias power for semiconductor applications.

2. Description of the Background Art

Integrated circuits have evolved into complex devices that can include millions of transistors, capacitors and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components are reduced to the sub-micron scale, it is now necessary to use low resistivity conductive materials (e.g., copper) as well as low dielectric constant insulating materials (dielectric constant less than about 4) to obtain suitable electrical performance from such components.

The demands for greater integrated circuit densities also impose demands on the process sequences used in the manufacture of integrated circuit components. For example, in process sequences that use conventional lithographic techniques, a layer of energy sensitive resist is formed over a stack of material layers disposed on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer. Thus, a highly selective etchant enhances accurate pattern transfer.

As the geometry limits of the structures used to form semiconductor devices are pushed against technology limits, the need for accurate pattern transfer for the manufacture of structures having small critical dimensions and high aspect ratios has become increasingly difficult. For example, the thickness of the energy sensitive resist has been reduced in order to control pattern resolution. Such thin resist layers (e.g., less than about 2000 Å) can be insufficient to mask underlying material layers during the pattern transfer step due to attack by the chemical etchant. An intermediate layer (e.g., silicon oxynitride, silicon carbine or carbon film), called a hardmask layer, is often used between the energy sensitive resist layer and the underlying material layers to facilitate pattern transfer because of its greater resistance to chemical etchants. When etching materials to form structures having aspect ratios greater than about 5:1 and/or critical dimensional less than about 50 nm, the hardmask layer utilized to transfer patterns to the materials is exposed to aggressive etchants for a significant period of time. After a long period of exposure to the aggressive etchants, the hardmask layer without sufficient etching resistance may be change, resulting in inaccurate pattern transfer and loss of dimensional control.

Accordingly, demand for a hardmask layer with high mechanical strength is significantly increasing. However, after forming such hardmask layer in a processing chamber, deposition residuals or build-ups remaining in the processing chamber are often hard to remove. Deposition residuals or build-ups accumulated on chamber components and surfaces of the processing chamber may become a source of unwanted particles that may contaminate the substrate. To maintain cleanliness of the processing chamber, a cleaning process is periodically performed after each or a number of substrates is processed in the processing chamber. However, as the deposition residuals or build-ups resulted from the high mechanical strength hardmask layer are often hard to remove, conventional cleaning process often does not have sufficient cleaning effect when cleaning the processing chamber, thereby adversely resulting in the processing chamber having insufficient cleanliness required to deposit high quality films.

Therefore, there is a need for an improved method for removing deposition residuals or build-ups accumulated on the chamber components after a deposition process so as to improve processing chamber cleanliness.

### SUMMARY

Methods for cleaning a processing chamber to remove amorphous carbon containing residuals from the processing chamber are provided. The cleaning process utilizes a low frequency RF bias power during the cleaning process. In one embodiment, a method of cleaning a processing chamber includes supplying a cleaning gas mixture into a processing chamber, applying a RF bias power of about 2 MHz or lower to a substrate support assembly disposed in the processing chamber to form a plasma in the cleaning gas mixture in the processing chamber, and removing deposition residuals from the processing chamber.

In another embodiment, a method for cleaning a processing chamber after an amorphous carbon layer disposed process includes performing an amorphous carbon layer deposition process on a substrate disposed in a processing chamber, and performing a cleaning process in the processing chamber after removing the substrate having the amorphous carbon layer deposited thereon, wherein the cleaning process further comprises supplying a cleaning gas mixture into the processing chamber, applying a RF bias power of about 2 MHz or lower to a substrate support assembly disposed in the processing chamber to form a plasma in the cleaning gas mixture in the processing chamber, and removing deposition residuals from the processing chamber.

In yet another embodiment, a method for cleaning a processing chamber after an amorphous carbon layer disposed process includes performing a cleaning process after a deposition process performed in the processing chamber, wherein the cleaning process further comprise supplying a cleaning gas mixture including at least an oxygen containing gas into a processing chamber, applying a RF bias power of about 2 MHz or lower to a substrate support assembly disposed in the processing chamber to form a plasma in the cleaning gas mixture in the processing chamber, and removing deposition residuals from the processing chamber.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic illustration of an apparatus suitable for practice one embodiment of the present invention;

FIG. 2 depicts another embodiment of schematic illustration of an apparatus suitable for practice one embodiment of the present invention; and

FIG. 3 depicts a flow diagram of a cleaning process for removing deposition residuals and built-ups according to one embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention provide methods for cleaning a processing chamber to remove amorphous carbon containing residuals and/or build-ups. In one embodiment, the processing chamber may be utilized to form an amorphous carbon layer suitable for use as a hardmask layer. After or prior to the deposition process, the cleaning process may be performed to remove amorphous carbon containing residuals and/or build-ups from the processing chamber so as to provide a deposition environment with a desired cleanliness needed to enable a high quality deposition process. In one embodiment, the cleaning process may be performed by utilizing a low frequency RF bias power applied during the cleaning process so as to enhance cleaning bottom portion of the processing chamber.

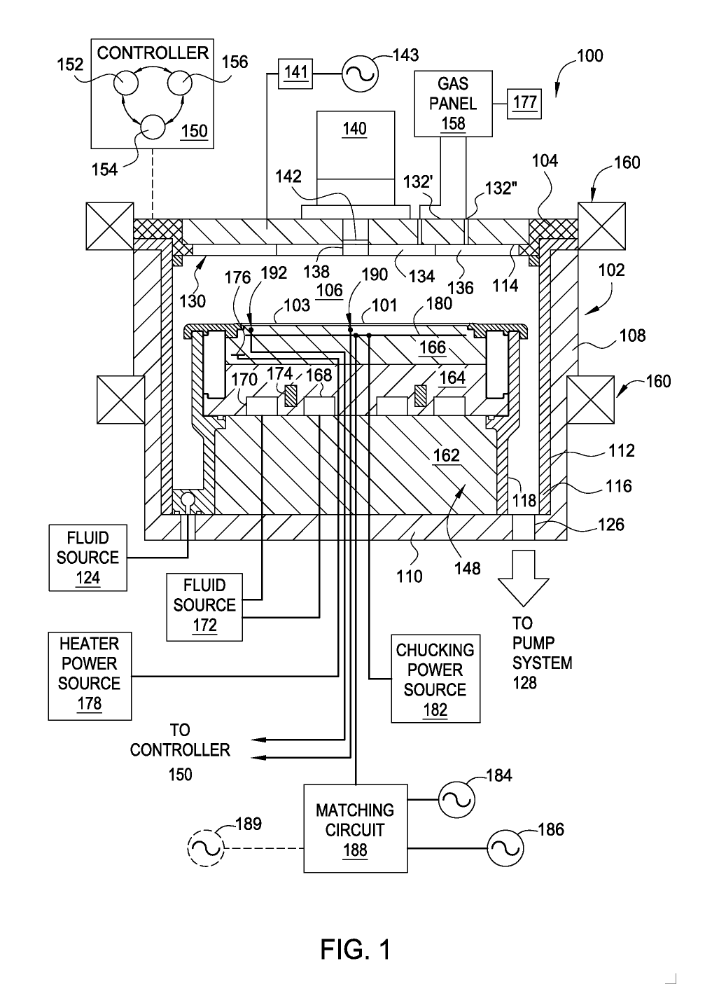

FIG. 1 is a sectional view of one embodiment of a processing chamber 100 suitable for performing a cleaning process to clean the processing chamber after or prior to an amorphous carbon layer deposition process. Suitable processing chambers that may be adapted for use with the teachings disclosed herein include, for example, a modified ENABLER® processing chamber available from Applied Materials, Inc. of Santa Clara, Calif. Although the processing chamber 100 is shown including a plurality of features that enable an amorphous carbon containing residuals and/or built-up cleaning process using a low frequency RF bias power, it is contemplated that other processing chambers may be adapted to benefit from one or more of the inventive features disclosed herein.

The processing chamber 100 includes a chamber body 102 and a lid 104 which enclose an interior volume 106. The chamber body 102 is typically fabricated from aluminum, stainless steel or other suitable material. The chamber body 102 generally includes sidewalls 108 and a bottom 110. A substrate access port (not shown) is generally defined in a sidewall 108 and a selectively sealed by a slit valve to facilitate entry and egress of a substrate 101 from the processing chamber 100. An exhaust port 126 is defined in the chamber body 102 and couples the interior volume 106 to a pump system 128. The pump system 128 generally includes one or more pumps and throttle valves utilized to evacuate and regulate the pressure of the interior volume 106 of the processing chamber 100. In one embodiment, the pump system 128 maintains the pressure inside the interior volume 106 at operating pressures typically between about 10 mTorr to about 20 Torr.

The lid 104 is sealingly supported on the sidewall 108 of the chamber body 102. The lid 104 may be opened to allow excess to the interior volume 106 of the processing chamber 100. The lid 104 includes a window 142 that facilitates optical process monitoring. In one embodiment, the window 142 is comprised of quartz or other suitable material that is transmissive to a signal utilized by an optical monitoring system 140.

The optical monitoring system 140 is positioned to view at least one of the interior volume 106 of the chamber body 102 and/or the substrate 101 positioned on a substrate support assembly 148 through the window 142. In one embodiment, the optical monitoring system 140 is coupled to the lid 104 and facilitates an integrated deposition process that uses optical metrology to provide information that enables process adjustment to compensate for incoming substrate pattern feature inconsistencies (such as thickness, and the like), provide process state monitoring (such as plasma monitoring, temperature monitoring, and the like) as needed. One optical monitoring system that may be adapted to benefit from the invention is the EyeD® full-spectrum, interferometric metrology module, available from Applied Materials, Inc., of Santa Clara, Calif.

A gas panel 158 is coupled to the processing chamber 100 to provide process and/or cleaning gases to the interior volume 106. In the embodiment depicted in FIG. 1, inlet ports 132′, 132″ are provided in the lid 104 to allow gases to be delivered from the gas panel 158 to the interior volume 106 of the processing chamber 100.

A showerhead assembly 130 is coupled to an interior surface 114 of the lid 104. The showerhead assembly 130 includes a plurality of apertures that allow the gases flowing through the showerhead assembly 130 from the inlet port 132 into the interior volume 106 of the processing chamber 100 in a predefined distribution across the surface of the substrate 101 being processed in the chamber 100.

A remote plasma source 177 may be coupled to the gas panel 158 to facilitate dissociating gas mixture from a remote plasma prior to entering into the interior volume 106 for processing. A RF power source 143 is coupled through a matching circuit 141 to the showerhead assembly 130. The RF power source 143 typically is capable of producing up to about 3000 W of power at a tunable frequency in a range from about 50 kHz to about 13.56 MHz.

The showerhead assembly 130 additionally includes a region transmissive to an optical metrology signal. The optically transmissive region or passage 138 is suitable for allowing the optical monitoring system 140 to view the interior volume 106 and/or substrate 101 positioned on the substrate support assembly 148. The passage 138 may be a material, an aperture or plurality of apertures formed or disposed in the showerhead assembly 130 that is substantially transmissive to the wavelengths of energy generated by, and reflected back to, the optical measuring system 140. In one embodiment, the passage 138 includes a window 142 to prevent gas leakage that the passage 138. The window 142 may be a sapphire plate, quartz plate or other suitable material. The window 142 may alternatively be disposed in the lid 104.

In one embodiment, the showerhead assembly 130 is configured with a plurality of zones that allow for separate control of gas flowing into the interior volume 106 of the processing chamber 100. In the embodiment FIG. 1, the showerhead assembly 130 as an inner zone 134 and an outer zone 136 that are separately coupled to the gas panel 158 through separate inlet ports 132.

The substrate support assembly 148 is disposed in the interior volume 106 of the processing chamber 100 below the showerhead assembly 130. The substrate support assembly 148 holds the substrate 101 during processing. The substrate support assembly 148 generally includes a plurality of lift pins (not shown) disposed therethrough that are configured to lift the substrate 101 from the substrate support assembly 148 and facilitate exchange of the substrate 101 with a robot (not shown) in a conventional manner. An inner liner 118 may closely circumscribe the periphery of the substrate support assembly 148.

In one embodiment, the substrate support assembly 148 includes a mounting plate 162, a base 164 and an electrostatic chuck 166. The mounting plate 162 is coupled to the bottom 110 of the chamber body 102 includes passages for routing utilities, such as fluids, power lines and sensor leads, among other, to the base 164 and the electrostatic chuck 166. The electrostatic chuck 166 comprises at least one clamping electrode 180 for retaining a substrate 101 below showerhead assembly 130. The clamping electrode 180 of the electrostatic chuck 166 is driven by a chucking power source 182 to develop an electrostatic force that holds the substrate 101 to the chuck surface, as is conventionally known. Alternatively, the substrate 101 may be retained to the substrate support assembly 148 by clamping, vacuum or gravity.

At least one of the base 164 or electrostatic chuck 166 may include at least one optional embedded heater 176, at least one optional embedded isolator 174 and a plurality of conduits 168, 170 to control the lateral temperature profile of the substrate support assembly 148. The conduits 168, 170 are fluidly coupled to a fluid source 172 that circulates a temperature regulating fluid therethrough. The heater 176 is regulated by a power source 178. The conduits 168, 170 and heater 176 are utilized to control the temperature of the base 164, thereby heating and/or cooling the electrostatic chuck 166. The temperature of the electrostatic chuck 166 and the base 164 may be monitored using a plurality of temperature sensors 190, 192. The electrostatic chuck 166 may further comprise a plurality of gas passages (not shown), such as grooves, that are formed in a substrate supporting surface of the chuck 166 and fluidly coupled to a source of a heat transfer (or backside) gas, such as He. In operation, the backside gas is provided at controlled pressure into the gas passages to enhance the heat transfer between the electrostatic chuck 166 and the substrate 101.

In one embodiment, the substrate support assembly 148 is configured as a cathode and includes an electrode 180 that is coupled to a plurality of RF power bias sources 184, 186. The RF bias power sources 184, 186 are coupled between the electrodes 180 disposed in the substrate support assembly 148 and another electrode, such as the showerhead assembly 130 or ceiling 104 of the chamber body 102. The RF bias power excites and sustains a plasma discharge formed from the gases disposed in the processing region of the chamber body 102.

In the embodiment depicted in FIG. 1, the dual RF bias power sources 184, 186 are coupled to the electrode 180 disposed in the substrate support assembly 148 through a matching circuit 188. The signal generated by the RF bias power sources 184, 186 is delivered through matching circuit 188 to the substrate support assembly 148 through a single feed to ionize the gas mixture provided in the plasma processing chamber 100, thereby providing ion energy necessary for performing a deposition or other plasma enhanced process. The RF bias power sources 184, 186 are generally capable of producing an RF signal having a frequency of from about 50 kHz to about 200 MHz and a power between about 0 Watts and about 5000 Watts. An additional bias power source 189 may be coupled to the electrode 180 to control the characteristics of the plasma.

In one mode of operation, the substrate 101 is disposed on the substrate support assembly 148 in the plasma processing chamber 100. A process gas and/or gas mixture is introduced into the chamber body 102 through the showerhead assembly 130 from the gas panel 158. Furthermore, additional gases may be supplied from the remote plasma source 177 through the showerhead assembly 130 to the processing chamber 100. A vacuum pump system 128 maintains the pressure inside the chamber body 102 while removing deposition by-products. The vacuum pump system 128 typically maintains an operating pressure between about 10 mTorr to about 20 Torr.

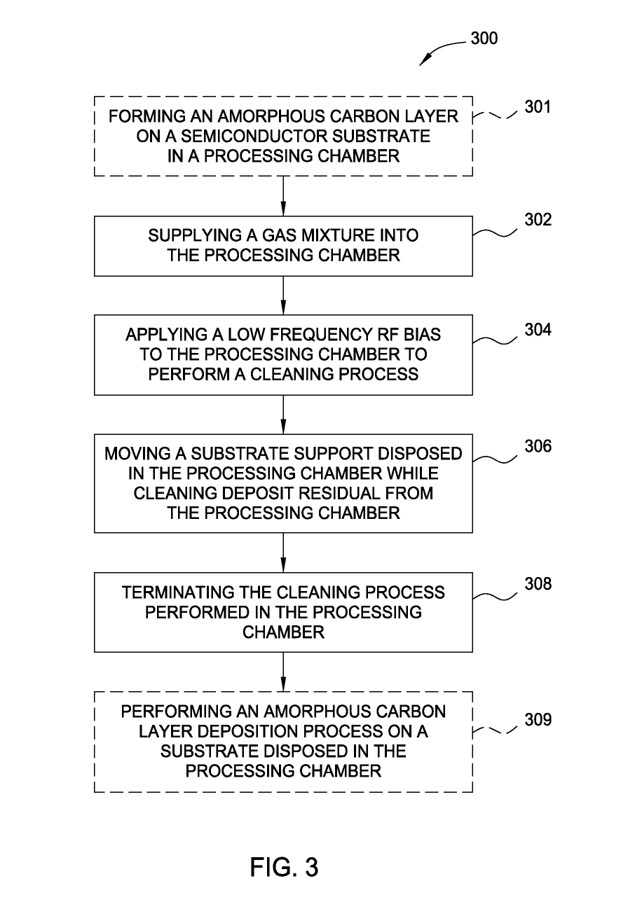

The RF power source 143 and the RF bias power sources 184, 186 provide RF source and bias power at separate frequencies to the anode and/or cathode through the matching circuits 141 and 188, respectively, thereby providing energy to form the plasma and excite the gas mixture in the chamber body 102 into ions to perform a plasma process, in this example, a cleaning process as further described below with reference to FIG. 3.

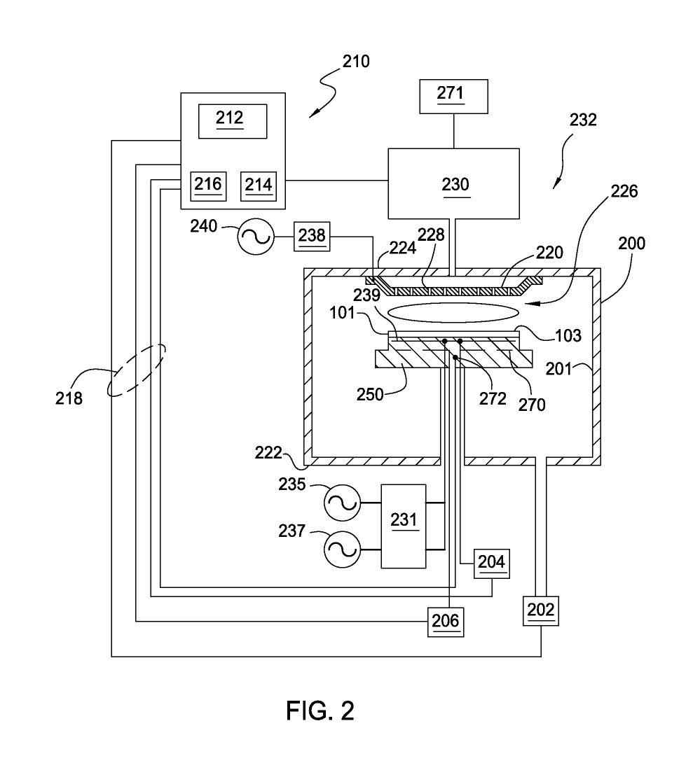

FIG. 2 is a schematic representation of another substrate processing process chamber 232 that can be used to perform a processing chamber cleaning process to clean amorphous carbon residuals and/or build-ups prior to or after an amorphous carbon layer deposition process in accordance with embodiments of the present invention. Other examples of systems that may be used to practice the invention include CENTURA®, PRECISION 5000® and PRODUCER® deposition systems, all available from Applied Materials Inc., Santa Clara, Calif. It is contemplated that other processing system, including those available from other manufacturers, may be adapted to practice the invention.

The processing process chamber 232 includes a process chamber 200 coupled to a gas panel 230 and a controller 210. The process chamber 200 generally includes a top 224, a side 201 and a bottom wall 222 that define an interior volume 226. A substrate support assembly 250 is provided in the interior volume 226 of the chamber 200. The substrate support assembly 250 may be fabricated from aluminum, ceramic, and other suitable materials. In one embodiment, the substrate support assembly 250 is fabricated by a ceramic material, such as aluminum nitride, which is a material suitable for use in a high temperature environment, such as a plasma process environment, without causing thermal damage to the substrate support assembly 250. The substrate support assembly 250 may be moved in a vertical direction inside the chamber 200 using a lift mechanism (not shown).

The substrate support assembly 250 may include an embedded heater element 270 suitable for controlling the temperature of a substrate 101 supported on the substrate support assembly 250. In one embodiment, the substrate support assembly 250 may be resistively heated by applying an electric current from a power supply 206 to the heater element 270. In one embodiment, the heater element 270 may be made of a nickel-chromium wire encapsulated in a nickel-iron-chromium alloy (e.g., INCOLOY®) sheath tube. The electric current supplied from the power supply 206 is regulated by the controller 210 to control the heat generated by the heater element 270, thereby maintaining the substrate 101 and the substrate support assembly 250 at a substantially constant temperature during film deposition. The supplied electric current may be adjusted to selectively control the temperature of the substrate support assembly 250 between about 100 degrees Celsius to about 780 degrees Celsius, such as greater than 500 degrees Celsius.

A temperature sensor 272, such as a thermocouple, may be embedded in the substrate support assembly 250 to monitor the temperature of the substrate support assembly 250 in a conventional manner. The measured temperature is used by the controller 210 to control the power supplied to the heater element 270 to maintain the substrate 101 at a desired temperature.

The substrate support assembly 250 comprises at least one clamping electrode 239 for retaining the substrate 101 below showerhead assembly 130. The clamping electrode 239 is driven by a chucking power source 204 to develop an electrostatic force that holds the substrate 101 to the substrate surface, as is conventionally known. Alternatively, the substrate 101 may be retained to the substrate support assembly 250 by clamping, vacuum or gravity.

In one embodiment, the substrate support assembly 250 is configured as a cathode and is coupled to a plurality of RF power bias power 235, 237. RF bias powers 235, 237 are coupled between an electrodes 239 disposed in the substrate support assembly 250 and another electrode, such as a showerhead assembly 220. The RF bias power excites and sustains a plasma discharge formed from the gases disposed in the processing chamber 100. In the embodiment depicted in FIG. 2, dual RF bias power sources 235, 237 are coupled to the electrode 239 through a matching circuit 231. The signal generated by the RF bias power sources 235, 237 is delivered through matching circuit 231 to the electrode 239 disposed in the substrate support assembly 250 through a single feed to ionize the gas mixture provided in the plasma process chamber 200, thereby providing ion energy necessary for performing a deposition or other plasma enhanced process. The RF bias power sources 235, 237 are generally capable of producing an RF signal having a frequency of from about 50 kHz to about 200 MHz and a power between about 0 Watts and about 5000 Watts. It is noted that another optional RF bias or source power may be used to control the characteristics of the plasma.

A vacuum pump 202 is coupled to a port formed in the walls of the chamber 200. The vacuum pump 202 is used to maintain a desired gas pressure in the process chamber 200. The vacuum pump 202 also evacuates post-processing gases and by-products of the process from the chamber 200.

The showerhead assembly 220 having a plurality of apertures 228 is coupled to the top 224 of the process chamber 200 above the substrate support assembly 250. The apertures 228 of the showerhead assembly 220 are utilized to introduce process gases into the chamber 200. The apertures 228 may have different sizes, number, distributions, shape, design, and diameters to facilitate the flow of the various process gases for different process requirements. The showerhead assembly 220 is connected to the gas panel 230 that allows various gases to supply to the interior volume 226 during process. A remote plasma source 271 may be coupled to the gas panel 230 to facilitate dissociating gas mixture from a remote plasma prior to entering into the interior volume 226 for processing. A plasma is formed from the process gas mixture exiting the showerhead assembly 220 to enhance thermal decomposition of the process gases resulting in the deposition of material on a surface 103 of the substrate 101.

The showerhead assembly 220 and substrate support assembly 250 may be formed a pair of spaced apart electrodes in the interior volume 226. One or more RF power sources 240, 235, 237 provide a source or bias potential through matching circuits 238, 231 respectively to the showerhead assembly 220, or to the substrate support assembly 250 to facilitate generation of a plasma between the showerhead assembly 220 and the substrate support assembly 250. Alternatively, the RF power sources 240, bias power sources 235, 237 and matching circuit 238, may be coupled to the showerhead assembly 220, substrate support assembly 250, or coupled to both the showerhead assembly 220 and the substrate support assembly 250, or coupled to an antenna (not shown) disposed exterior to the chamber 200 in an alternative arrangement. In one embodiment, the RF power source 240 may provide power at between about 500 Watts and about 3000 Watts at a frequency of about 50 kHz to about 13.56 MHz.

The controller 210 includes a central processing unit (CPU) 212, a memory 216, and a support circuit 214 utilized to control the process sequence and regulate the gas flows from the gas panel 230. The CPU 212 may be of any form of a general purpose computer processor that may be used in an industrial setting. The software routines can be stored in the memory 216, such as random access memory, read only memory, floppy, or hard disk drive, or other form of digital storage. The support circuit 214 is conventionally coupled to the CPU 212 and may include cache, clock circuits, input/output systems, power supplies, and the like. Bi-directional communications between the controller 210 and the various components of the processing process chamber 232 are handled through numerous signal cables collectively referred to as signal buses 218, some of which are illustrated in FIG. 2.

The above chambers are described above mainly for illustrative purposes, and other plasma processing chambers may also be employed for practicing embodiments of the invention.

FIG. 3 illustrates a process flow diagram of a method 300 for cleaning a processing chamber, such as the processing chamber 100 depicted in FIG. 1 or the processing chamber 232 depicted in FIG. 2, prior to or after an amorphous carbon layer deposition process.

The method 300 begins at an optional step 301 by transferring a substrate, such as the substrate 101 depicted in FIGS. 1-2 into a suitable processing chamber, such as but not limited to the processing chamber 100 depicted in FIG. 1 or alternatively the processing chamber 232 depicted in FIG. 2. In the embodiment wherein the optional step 301 is not performed, the method 300 may be performed by beginning at step 302 to perform a cleaning process in the processing chamber. At optional step 301, the substrate 101 may have a substantially planar surface, an uneven surface, or a substantially planar surface having a structure formed thereon. In one embodiment, the substrate 101 may have material layers being a part of a film stack utilized to form a gate structure, a contact structure, an interconnection structure or shallow trench isolation (STI) structure in the front end or back end processes. In embodiments wherein the material layer is not present, the optional step 301 may be directly formed in the substrate 101.

In one embodiment, the material layer maybe a silicon layer utilized to form a gate electrode. In another embodiment, the material layer may include a silicon oxide layer, a silicon oxide layer deposited over a silicon layer. In yet another embodiment, the material layer may include one or more layers of other dielectric materials utilized to fabricate semiconductor devices. Suitable examples of the dielectric layers include silicon oxide, silicon nitride, silicon oxynitride, silicon carbide, or any suitable low-k or porous dielectric material as needed. In still another embodiment, the material layer does not include any metal layers.

An amorphous carbon deposition process is then deposited at the optional step 301 to form an amorphous carbon layer on the substrate 101. The amorphous carbon deposition process may be performed by supplying a deposition gas mixture into the processing chamber 100, 232 for the deposition process. The deposition gas mixture includes at least a hydrocarbon gas and an inert gas. In one embodiment, hydrocarbon gas has a formula CₓH_{y}, where x has a range between 1 and 12 and y has a range of between 4 and 26. More specifically, aliphatic hydrocarbons include, for example, alkanes such as methane, ethane, propane, butane, pentane, hexane, heptane, octane, nonane, decane and the like; alkenes such as propene, ethylene, propylene, butylene, pentene, and the like; dienes such as hexadiene butadiene, isoprene, pentadiene and the like; alkynes such as acetylene, vinylacetylene and the like. Alicyclic hydrocarbons include, for example, cyclopropane, cyclobutane, cyclopentane, cyclopentadiene, toluene and the like. Aromatic hydrocarbons include, for example, benzene, styrene, toluene, xylene, pyridine, ethylbenzene, acetophenone, methyl benzoate, phenyl acetate, phenol, cresol, furan, and the like. Additionally, alpha-terpinene, cymene, 1,1,3,3,-tetramethylbutylbenzene, t-butylether, t-butylethylene, methyl-methacrylate, and t-butylfurfurylether may be utilized. Additionally, alpha-terpinene, cymene, 1,1,3,3,-tetramethylbutylbenzene, t-butylether, t-butylethylene, methyl-methacrylate, and t-butylfurfurylether may be selected. In an exemplary embodiment, the hydrocarbon compounds are propene, acetylene, ethylene, propylene, butylenes, toluene, alpha-terpinene. In a particular embodiment, the hydrocarbon compound is propene (C₃H₆) or acetylene.

Alternatively, one or more hydrocarbon gas may be mixed with the hydrocarbon gas in the deposition gas mixture supplied to the process chamber. A mixture of two or more hydrocarbon gas may be used to deposit the amorphous carbon layer. The inert gas, such as argon (Ar) or helium (He), is supplied with the gas mixture into the process chamber 100, 232. Other carrier gases, such as nitrogen (N₂) and nitric oxide (NO), hydrogen (H₂), ammonia (NH₃), a mixture of hydrogen (H₂) and nitrogen (N₂), or combinations thereof may also be used to control the density and deposition rate of the amorphous carbon layer. The addition of H₂ and/or NH₃ may be used to control the hydrogen ratio (e.g., carbon to hydrogen ratio) of the deposited amorphous carbon layer. The hydrogen ratio present in the amorphous carbon layer provides control over layer properties, such as reflectivity, stress, transparency and density. In one embodiment, an inert gas, such as argon (Ar) or helium (He) gas, is supplied with the hydrocarbon gas, such as propene (C₃H₆) or acetylene, into the process chamber to deposit the amorphous carbon layer. The inert gas provided in the deposition gas mixture may assist control of the optical and mechanical properties of the as-deposited layer, such as the index of refraction (n) and the absorption coefficient (k), hardness, density and elastic modulus of the amorphous carbon layer to be deposited on substrate 101.

During deposition, a remote plasma RF power of between about 50 Watts to about 5000 Watts may be supplied to the processing chamber. A RF source power of between about 450 Watts to about 1000 Watts may be applied to maintain a plasma formed from the gas mixture. In one embodiment, while applying the RF source power to the processing chamber, dual RF frequency bias power may be supplied to the processing chamber to assist forming a plasma in the deposition gas mixture. The dual RF frequency bias power may be applied to an electrode, such as a showerhead assembly or a substrate, or both disposed in the processing chamber. In the embodiment depicted herein, the dual RF frequency bias power is applied to a cathode, such as the substrate support assembly 148 or 250 depicted in FIGS. 1-2 respectively. In one embodiment, a first RF bias power is selected to generate a bias power at a first frequency of about 2 MHz and the second RF bias power is selected to generate power at a second frequency of about 60 MHz. The RF bias powers provide up to about 3000 Watts of total RF power in a predetermined power ratio of the first bias power to the second bias power of between 1:10 and 10:1. It is believed that the first frequency of the first RF bias power provides a broad ion energy distribution (e.g., lower frequency). The second frequency of the second RF bias power provides a peaked, well defined ion energy distribution (e.g., higher frequency). The mixing of the two bias frequencies is used to tune the energy distribution about this average acceleration generated by this DC potential. Thus, utilizing a plasma enhanced processing chamber with a dual frequency RF bias power, the ion energy distribution within the plasma can be controlled.

In one embodiment, a deposition process window is advantageously widened by mixing a high frequency (e.g., 13.56 MHz, 60 MHz, 162 MHz, or higher) and a low frequency (e.g., 2 MHz or lower) bias RF signal with different mixing ratio in a wide total power range. The ratio of the bias power of the two bias frequencies can be advantageously utilized to control the ion energy distribution and plasma sheath, thereby facilitating the flexibility to control amount of carbon elements generated in the process chamber and the bonding energy as formed. In one example, when a 50 percent of 2 MHz first RF bias power and a 50 percent 60 MHz second bias power is selected, an effective bias power of about 31 MHz RF bias power may be obtained. By manipulating plasma ion distribution and sheath as generated at different RF bias frequency, a desired film high density as formed in the amorphous carbon layer with desired low stress level may be obtained and balanced. In one embodiment, a ratio of a first bias power with a first frequency to the second bias power with a second frequency may be applied to the processing chamber at between about 1:10 and 10:1, such as between about 8:1 and about 1:5, for example about 7:1 and about 1:1. The first frequency is a relatively high frequency greater than 10 MHz, such as between about 10.5 MHz and about 200 MHz. The second frequency is a relatively lower frequency less than 8 MHz, such as between about 0.1 MHz and about 7 MHz. The first RF bias power of between about 100 Watts to about 2000 Watts, such as 150 Watts to about 900 Watts may be applied to the processing chamber. The second RF bias power of between about 100 Watts to about 3000 Watts, such as 500 Watts to about 2000 Watts, may be applied to the processing chamber.

Several process parameters may also be controlled during the deposition process. The substrate temperature may be controlled between about 300 degrees Celsius and about 800 degrees Celsius. The hydrocarbon compound, such as propene (C₃H₆), may be supplied in the gas mixture at a rate between about 400 sccm and about 2000 sccm. The inert gas, such as Ar gas, may be supplied in the gas mixture at a rate between about 1200 sccm and about 8000 sccm. The process pressure may be maintained at about 1 Torr to about 20 Torr. The spacing between the substrate and showerhead may be controlled at about 200 mils to about 1000 mils. It is noted that the hydrocarbon gas may be supplied from a remote plasma source, such as the remote plasma source 177, 271 depicted in FIGS. 1 and 2, to assist dissociating hydrocarbon gas to be supplied into the chamber for processing.

After the deposition process at the optional step 301, an amorphous carbon layer may be formed on the substrate 101. Under dual RF bias frequency along with desired power ratio between the high and low RF bias frequency, film properties, with desired film density along with film stress and film transparency, may be advantageously obtained. In one embodiment, a film density greater than 1.6 g/cc, such as between about 1.7 g/cc and about 2.3 g/cc may be obtained.

It is noted that the amorphous carbon layer deposition process performed at step 301 may be any other suitable deposition process, with or without dual RF bias frequency applications, including CVD, ALD, PVD, or the like.

At step 302, a cleaning gas mixture may be supplied into the processing chamber 100, 232 to commence a processing chamber cleaning process. In one embodiment, the cleaning gas mixture may include at least one oxygen containing gas. As the residuals and/or build-ups remaining in the processing chamber may most likely be carbon based materials (from the previous deposition process performed at the optional step 301), oxygen containing gas may be utilized to remove the carbon containing residuals and/or build-ups. The oxygen containing gas may react with the carbon containing residuals and/or build-ups to form carbon oxide gas, carbon hydrogen gas or other carbon containing byproduct, which can be pumped out of the processing chamber. Suitable examples of the oxygen containing gas include O₂, H₂O, and O₃. A carrier gas, inert gas or some other gas may also be added into the gas mixture to assist flowing the oxygen containing gas into the processing chamber for processing and promote complete reaction with the carbon residues. Suitable examples of the carrier gas include N₂, O₂, N₂O, NO₂, NH₃, H₂O, H₂, O₃, and the like. Suitable examples of the inert gases include N₂, Ar, He, Xe and Kr gas.

Alternatively, the cleaning gas mixture may include an additional fluorine containing gas. The fluorine containing gas is dissociated as reactive etchants by the plasma formed from the cleaning gas mixture. The fluorine ions dissociated from the fluorine containing gas in the cleaning gas mixture may react with and attack carbon containing residuals and/or build-ups so as to assist removing them from the processing chamber. Suitable examples of the fluorine containing gas may include NF₃, C₄F₆, C₄F₈, C₂F₂, CF₄, CHF₃, C₂F₆, C₄F₆, C₅F₈, CH₂F₂, SF₆ and the like. In an exemplary embodiment, the fluorine containing gas used in the cleaning gas mixture is NF₃. In one particular embodiment, the cleaning gas mixture includes O₂, Ar and optional NF₃ gas.

At step 304, while supplying the cleaning gas mixture into the processing chamber, a low frequency RF bias power may be applied to the processing chamber. It is believed that the low frequency RF bias power supplied to one of the electrode, either to the substrate support assembly 148 or 250 or the showerhead assembly 130, 220 depicted in FIGS. 1-2, may assist cleaning a bottom of the processing chamber, as low frequency RF bias power may provide more ion energy with vertical and straight ion profiles. In contrast, it is believed that high frequency RF bias power have a progressively much more concentrated ion/plasma density. Thus, by selecting RF bias power with different frequencies, ion directions may be efficiently controlled, thereby promoting localized cleaning efficiency. The trajectory and direction of the ions accelerated by the selected low frequency RF power may promote the cleaning efficiency at a target location in the processing chamber, thereby assisting localized cleaning efficiency at a particular position, such as around the substrate support assembly 148, 250 or bottom portion of the processing chamber (i.e., below the upper surface of the substrate support assembly 148, 250.

In one embodiment, the low frequency RF power as utilized during the cleaning process may have a low frequency at about 2 MHz or lower supplied to one of the electrodes, such as the substrate support assembly or a showerhead, such as the substrate support assembly. In one example, the low frequency RF power is selected to generate a bias power at a low frequency of about 2 MHz. The low frequency RF bias power may be provided between about 100 Watts and about 2000 Watts to the processing chamber.

In addition to the low frequency RF bias power applied during the cleaning process, RF source power may also be applied along with the low frequency RF bias power. As shown in FIGS. 1 and 2, the RF power sources 143, 240 may apply power to the showerhead assembly 130, 220 while the low frequency RF bias power may be applied to the substrate support assembly 148 or 250. The RF source power may be applied to maintain a plasma in the cleaning gas mixture. For example, a RF source power of about 100 Watts to about 1000 Watts at a frequency of about 13.56 mHz or 60 mHz may be applied to maintain a plasma inside the processing chamber.

In some embodiments, power from the RPS (remote plasma source) 177, 271 may also be applied to the processing chamber during the cleaning process, if necessary. The RPS (remote plasma source) power may be applied to the processing chamber along with the low frequency RF bias power with or without the RF source power. In one embodiment, the RPS power applied during the cleaning process is between about 1000 Watts and about 10000 Watts.

During the cleaning process, several process parameters may be regulated to control the cleaning process. In one exemplary embodiment, a process pressure in the processing chamber is regulated between about 100 mTorr to about 10000 mTorr. A substrate temperature is maintained between about 15 degrees Celsius to about 450 degrees Celsius.

At step 306, during the cleaning process, the substrate support assembly 148 or 250 may be moved vertically to facilitate cleaning bottom portion, e.g., adjacent to and below the top surface of the substrate support assembly 148 or 250, of the processing chamber 100, 232. During the substrate, a substrate may or may not be on the substrate support assembly 149, 250. In some cases, a dummy substrate may be utilized and disposed on the substrate support assembly 148, 150 if necessary. As discussed above, in the conventional cleaning process, the plasma with the cleaning reactants is generally distributed above the substrate support assembly 148, 250, thereby often primarily cleaning the chamber sidewalls, or surfaces above the substrate support assembly 148, 250. Thus, by utilizing a low frequency RF bias power, which may provide ions with vertical directionality to reach to the chamber bottom, along with the movement of the substrate support assembly 148, 250 during the cleaning process, a greater amount of cleaning reactants from the plasma may reach underneath the substrate support assembly 148, 250 to the bottom portion of the processing chamber, thereby efficiently removing deposition residuals and/or build-ups located in the bottom portion of the processing chamber. In the mean while, the plasma generally remaining above the substrate support assembly 148, 250 may primarily remove deposition residuals and/or build-ups on the chamber sidewalls, ceiling, exposed surfaces above the substrate support assembly 148, 250 or other portions of the chamber body. In some cases, the RPS power and/or the RF source power supplied during the cleaning process may also assist removing deposition residuals and/or build-ups generally above the substrate support assembly 148.

In one embodiment, the substrate support assembly 148, 250 is controlled between about 100 mils and about 800 mils during cleaning process. In one particular embodiment, during the cleaning process, the substrate support assembly is vertically moved between about 200 mils and about 700 mils. The movement of the substrate support assembly may be continuously or intermittingly or reciprocating over a predetermined time period, such as between about 0.01 seconds and about 5 seconds as needed.

At step 308, after the cleaning process has been performed for a predetermined period of time and the deposition residuals and/or built-ups has been substantially removed and cleaned from the processing chamber, the cleaning process may then be terminated, providing a clean environment for substrates subsequently transferred into the processing chamber for an amorphous carbon deposition process. In one embodiment, the cleaning process may be performed for between about 60 seconds and about 600 seconds.

At an optional step 309, after the cleaning process, an amorphous carbon layer deposition process, similar to the deposition process depicted at step 301, may be then optionally performed to deposit an amorphous carbon layer on a substrate as needed. It is noted that the deposition process at step 301 or 309 and the cleaning process from step 302 to step 308 may be cyclically/continuously performed to maintain periodic cleaning (after each substrate process or a number of substrates processing) to ensure cleanliness of the processing chamber as needed.

Thus, methods for performing a cleaning process to remove deposition residuals and/or built-ups are provided. The cleaning method utilizes a low RF bias power during the cleaning process which may advantageously clean a bottom portion of the processing chamber, thus providing a thorough cleaning process to the processing chamber. The cleaning method may be suitable to clean other processing chambers prior to or after plasma processing as needed.

While the foregoing is directed to embodiments of the present invention, other and further embodiments of the invention may be devised without departing from the basic scope thereof, and the scope thereof is determined by the claims that follow.

What is claimed is:

1. A method of cleaning a processing chamber, comprising:
supplying a cleaning gas mixture into a processing chamber;
applying a RF bias power of about 2 MHz or lower to a substrate support assembly disposed in the processing chamber to form a plasma in the cleaning gas mixture in the processing chamber; and
removing deposition residuals from the processing chamber.

2. The method of claim 1, wherein applying the RF bias power to the processing chamber further comprises:
vertically moving the substrate support assembly while applying the RF bias power thereto.

3. The method of claim 1, wherein applying the RF bias power to the processing chamber further comprises:
applying a RF source power to the processing chamber.

4. The method of claim 1, wherein applying the RF bias power to the processing chamber further comprises:
applying a remote plasma power to the processing chamber.

5. The method of claim 1, wherein the cleaning gas mixture includes at least an oxygen containing gas.

6. The method of claim 5, wherein the oxygen containing gas is selected from a group consisting of O₂, H₂O, and O₃.

7. The method of claim 3, wherein the RF source power is applied to a showerhead assembly disposed in the processing chamber.

8. The method of claim 1, wherein the cleaning gas mixture includes a fluorine containing gas.

9. The method of claim 8, wherein the fluorine containing gas is selected from a group consisting of NF₃, C₄F₆, C₄F₈, C₂F₂, CF₄, CHF₃, C₂F₆, C₄F₆, C₅F₈, CH₂F₂ and SF₆.

10. The method of claim 1, wherein the cleaning gas mixture includes O₂, Ar and NF₃.

11. The method of claim 1, further comprising:
performing an amorphous carbon layer deposition process on a substrate disposed in the processing chamber after the processing chamber is cleaned.

12. The method of claim 1, further comprising:
performing an amorphous carbon layer deposition process on a substrate disposed in the processing chamber prior to supplying the cleaning gas mixture into the processing chamber for cleaning.

13. A method for cleaning a processing chamber after an amorphous carbon layer disposed process comprising:
performing an amorphous carbon layer deposition process on a substrate disposed in a processing chamber; and
performing a cleaning process in the processing chamber after removing the substrate having the amorphous carbon layer deposited thereon, wherein the cleaning process further comprises:
supplying a cleaning gas mixture into the processing chamber;
applying a RF bias power of about 2 MHz or lower to a substrate support assembly disposed in the processing chamber to form a plasma in the cleaning gas mixture in the processing chamber; and
removing deposition residuals from the processing chamber.

14. The method of claim 13, wherein applying the RF bias power to the processing chamber further comprises:
vertically moving the substrate support assembly while applying the RF bias power thereto.

15. The method of claim 13, wherein applying the RF bias power to the processing chamber further comprises:
applying a RF source power to the processing chamber.

16. The method of claim 13, wherein applying the RF bias power to the processing chamber further comprises:
applying a remote plasma power to the processing chamber.

17. The method of claim 13, wherein the cleaning gas mixture includes at least an oxygen containing gas.

18. The method of claim 15, wherein the RF source power is applied to a showerhead assembly disposed in the processing chamber.

19. The method of claim 13, wherein the cleaning gas mixture includes O₂, Ar and NF₃.

20. A method for cleaning a processing chamber after an amorphous carbon layer disposed process comprising:
performing a cleaning process after a deposition process performed in the processing chamber, wherein the cleaning process further comprises:
supplying a cleaning gas mixture including at least an oxygen containing gas into a processing chamber;
applying a RF bias power of about 2 MHz or lower to a substrate support assembly disposed in the processing chamber to form a plasma in the cleaning gas mixture in the processing chamber; and
removing deposition residuals from the processing chamber.
